(19) United States
(12) Patent Application Publication
(10) Pub. No.: US 2013/0153014 A1
(43) Pub. Date: Jun. 20, 2013

(54) PHOTOELECTRIC CONVERTER AND METHOD OF MANUFACTURING PHOTOELECTRIC CONVERTER

(71) Applicants: Ryo Matsuoka, Higashiomi-shi (JP); Manabu Kyuzo, Higashiomi-shi (JP); Nobuyuki Horiuchi, Higashiomi-shi (JP); Rui Kamada, Higashiomi-shi (JP); Daisuke Toyota, Higashiomi-shi, (JP); Yoshihide Okawa, Higashiomi-shi, (JP)

(72) Inventors: Ryo Matsuoka, Higashiomi-shi (JP); Manabu Kyuzo, Higashiomi-shi (JP); Nobuyuki Horiuchi, Higashiomi-shi (JP); Rui Kamada, Higashiomi-shi (JP); Daisuke Toyota, Higashiomi-shi, (JP); Yoshihide Okawa, Higashiomi-shi, (JP)

(73) Assignee: KYOCERA CORPORATION, Kyoto-shi, Kyoto (JP)

(21) Appl. No.: 13/810,788

(22) PCT Filed: Sep. 26, 2011
(86) PCT No.: PCT/JP2011/071793

§ 371 Date: Mar. 5, 2013

(30) Foreign Application Priority Data
Sep. 28, 2010 (JP) 2010-216480

(51) Int. Cl. H01L 31/065; H01L 31/18

(52) U.S. Cl. CPC H01L 31/065; H01L 31/18
USPC 136/255; 438/93

(57) ABSTRACT

A photoelectric converter is disclosed. The photoelectric converter includes an electrode layer and a semiconductor layer. The semiconductor layer is on the electrode layer. The semiconductor layer contains a chalcopyrite compound semiconductor. The semiconductor layer comprises a plurality of sub-layers. The plurality of sub-layers comprises a first sub-layer. The first sub-layer is located closest to the electrode layer. The first sub-layer has a first thickness smaller than an average thickness of the rest of the plurality of sub-layers.

### TECHNICAL FIELD

The present invention relates to a photoelectric converter containing a compound semiconductor and a method of manufacturing the same.

### BACKGROUND ART

A solar cell is one including a photoelectric converter including a light-absorbing layer made of a chalcopyrite compound semiconductor such as a Group I-III-VI compound semiconductor. The photoelectric converter includes, for example, a substrate made of soda-lime glass and a first electrode layer which is placed on the substrate, which serves as a back-side electrode, and which is made of Mo. The light-absorbing layer is placed on the first electrode layer. The light-absorbing layer is overlaid with a transparent second electrode layer made of ZnO, ITO, or the like with a buffer layer, made of ZnS, CdS, In₂S₃, or the like, placed therebetween. Such a photoelectric converter is disclosed in, for example, Japanese Unexamined Patent Application Publication No. 08-330614.

### SUMMARY OF INVENTION

Photoelectric converters need to be further improved in photoelectric conversion efficiency. Accordingly, it is an object of the present invention to provide a photoelectric converter having high photoelectric conversion efficiency.

A photoelectric converter according to an embodiment of the present invention includes an electrode layer and a semiconductor layer which includes a plurality of sub-layers stacked on the electrode layer and which contains a chalcopyrite compound semiconductor. A first one of the sub-layers of the semiconductor layer has a thickness less than the average thickness of the other sub-layers other than the first one, the first one being located closest to the electrode layer.

A method of manufacturing a photoelectric converter according to an embodiment of the present invention includes a step of forming a first precursor layer containing a constituent element of a chalcopyrite compound semiconductor on an electrode layer, a step of forming a second precursor layer on the first precursor layer such that the second precursor layer contains the constituent element of the chalcopyrite compound semiconductor and is thicker than the first precursor layer, and a step of heating the first precursor layer and the second precursor layer to form a semiconductor layer containing the chalcopyrite compound semiconductor.

According to any of a photoelectric converter according to an embodiment of the present invention and a method of manufacturing a photoelectric converter according to an embodiment of the present invention, a photoelectric converter having high photoelectric conversion efficiency can be provided.

### BRIEF DESCRIPTION OF DRAWINGS

FIG. 1 is a perspective view of an exemplary photoelectric converter according to an embodiment.

FIG. 2 is a sectional view of the photoelectric converter shown in FIG. 1.

### DESCRIPTION OF EMBODIMENTS

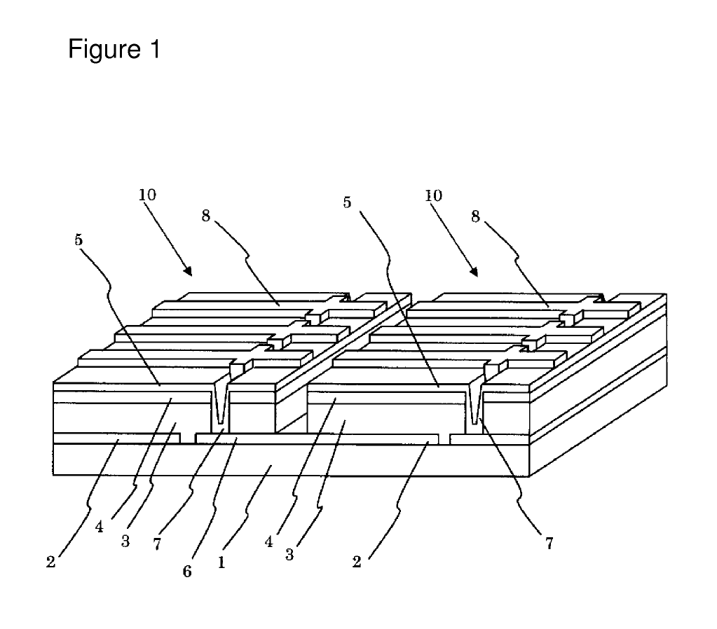

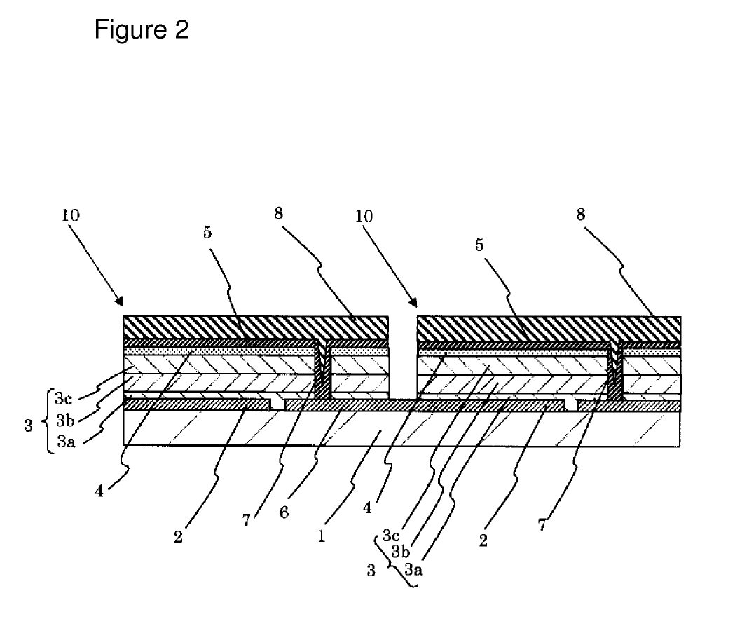

FIG. 1 is a perspective view of an exemplary photoelectric converter according to an embodiment of the present invention and FIG. 2 is a sectional view thereof. The photoelectric converter 10 includes a substrate 1, a first electrode layer 2, a first semiconductor layer 3, a second semiconductor layer 4, and a second electrode layer 5. This embodiment exemplifies, but is not limited to, an example in which the first semiconductor layer 3 serves as a light-absorbing layer and the second semiconductor layer 4 serves as a buffer layer bonded to the first semiconductor layer 3. The second semiconductor layer 4 may serve as a light-absorbing layer. In this embodiment, the photoelectric converter 10 has, but is not limited to, a configuration in which light is incident on the second electrode layer 5. Light may be incident on the substrate 1.

With reference to FIGS. 1 and 2, a plurality of photoelectric converters 10 are arranged. The photoelectric converters 10 each include a third electrode layer 6 which is located on the substrate 1 side of the first semiconductor layer 3 and which is spaced from the first electrode layer 2. The second electrode layer 5 is electrically connected to the third electrode layer 6 through a connection conductor 7 attached to the first semiconductor layer 3. The third electrode layers 6 extend from the first electrode layers 2 of the neighboring photoelectric converters 10. This configuration allows the photoelectric converters 10 to be connected to each other in series. In one of the photoelectric converters 10, the connection conductor 7 extends through the first semiconductor layer 3 and the second semiconductor layer 4 and photoelectric conversion is performed in the first semiconductor layer 3 and second semiconductor layer 4 sandwiched between the first electrode layer 2 and the second electrode layer 5.

The substrate 1 supports the photoelectric converters 10. Examples of a material used in the substrate 1 include glass, ceramic, resin, and metal.

The first electrode layer 2 and the third electrode layer 6 are made of a conductor such as Mo, Al, Ti, or Au and are formed on the substrate 1 by a sputtering process, a vapor deposition process, or the like.

The first semiconductor layer 3 is made of a compound semiconductor (hereinafter referred to as the chalcopyrite compound semiconductor) having a chalcopyrite structure. The chalcopyrite compound semiconductor may be a Group I-III-VI compound semiconductor having high photoelectric conversion efficiency. The Group I-III-VI compound semiconductor is a compound semiconductor containing a Group I-B element (as used herein, the notation for groups follows the conventional IUPAC periodic table and the Group I-B element is also referred to as a group 11 element in the new IUPAC periodic table), a Group III-B element (also referred to as a group 13 element), and a Group VI-B element (also referred to as a group 16 element). Examples of the Group I-III-VI compound semiconductor include Cu(In, Ga)Se₂ (also referred to as CIGS), Cu(In, Ga)(Se, S)₂ (also referred to as CIGSS), and CuInS₂ (also referred to as CIS). The term “Cu(In, Ga)Se₂” refers to a compound which is principally composed of Cu, at least one of In and Ga, and Se and which is represented by Cu(InₓGa₁₋ₓ)Se₂, where 0<x<1. The term “Cu(In, Ga)(Se, S)₂” refers to a compound which is principally composed of Cu, at least one of In and Ga, and at least one of Se and S and which is represented by Cu(InₓGa₁₋ₓ)(Se_{y}S_{2-y}), where 0<x<1 and 0<y<2.

With reference to FIG. 2, the first semiconductor layer 3 has a configuration in which a plurality of, that is, two or more semiconductor sub-layers (a first sub-layer 3a, a second sub-layer 3b, and a third sub-layer 3c are stacked on the first electrode layer 2 in that order as shown in FIG. 2) containing the chalcopyrite compound semiconductor are stacked. Among the semiconductor layers 3a to 3c, the first sub-layer 3a is located closest to the first electrode layer 2 and has a thickness less than the average thickness of the sub-layers 3b and 3c other than the first sub-layer 3a. The average thickness of the sub-layers 3b and 3c is one obtained in such a manner that the average thickness T_{b} of the second sub-layer 3b and the average thickness T_{c} of the third sub-layer 3c are determined and are then averaged. This configuration is capable of suppressing that cracks due to thermal stress extend through the first semiconductor layer 3 in a thickness direction thereof during the operation or manufacture of the photoelectric converter 10. Therefore, the photoelectric conversion efficiency can be increased by suppressing the occurrence of leakage. That is, even if cracks are caused in the first semiconductor layer 3 by thermal stress, the progress of the cracks can be suppressed at boundaries between the sub-layers because the first semiconductor layer 3 has such a layered structure. Furthermore, since the first sub-layer 3a is thinner than the other sub-layers, the occurrence of cracks in the first sub-layer 3a can be suppressed and therefore the electrical connection of the first sub-layer 3a to the first electrode layer 2 can be kept better.

In particular, among the sub-layers 3a to 3c, the first sub-layer 3a, which is located closest to the first electrode layer 2, is thinner than the other sub-layers 3b and 3c. This allows charge transfer in the second and third sub-layers 3b and 3c to be good and also allows the photoelectric converter 11 to have higher photoelectric conversion efficiency.

The boundaries between the first to third sub-layers 3a to 3c correspond to the interface between the first sub-layer 3a and the second sub-layer 3b and the interface between the second sub-layer 3b and the third sub-layer 3c as shown in FIG. 2. In the boundaries therebetween, grain boundaries between crystals contained in each sub-layer are substantially oriented in substantially the same plane perpendicular to the stacking direction of the first to third sub-layers 3a to 3c. In this case, sites where grain boundaries that form an angle of 10 degrees or less with a direction perpendicular to the stacking direction of the first to third sub-layers 3a to 3c are oriented in substantially the same plane can be regarded as the boundaries therebetween. The direction of these grain boundaries can be observed with, for example, a transmission electron microscope (TEM) or the like.

The thickness of the first sub-layer 3a may be 0.5 times or less the thickness of the other sub-layers (the second and third sub-layers 3b and 3c). From the viewpoint of enhancing the electrical connection of the first sub-layer 3a to the first electrode layer 2, the thickness of the first sub-layer 3a may be 0.08 to 0.4 times the thickness of the other sub-layers.

From the viewpoint of increasing the photoelectric conversion efficiency, the first semiconductor layer 3 may have a thickness of 1.0 μm to 2.5 μm. In this case, the first sub-layer 3a has a thickness of 0.2 μm to 1.0 μm. On the other hand, the second and third sub-layers 3b and 3c have a thickness of 0.5 μm to 1.5 μm.

The boundary between the first sub-layer 3a and the second sub-layer 3b may have a plurality of voids. The progress of cracks can be suppressed by such voids. When the boundary between the first sub-layer 3a and the second sub-layer 3b has the voids, the contact area between the first sub-layer 3a and the second sub-layer 3b may be less than the contact area between the first electrode layer 2 and the first sub-layer 3a. This allows the boundary between the first sub-layer 3a and the second sub-layer 3b to have an increased number of voids to successfully suppress the progress of cracks and also allows the charge generated in the first semiconductor layer 3 to be efficiently transferred to the first electrode layer 2 through the boundary between the first electrode layer 2 and the first sub-layer 3a to increase the photoelectric conversion efficiency. In this case, the contact area between the first electrode layer 2 and the first sub-layer 3a may be 0.60 to 0.95 times the contact area between the first sub-layer 3a and the second sub-layer 3b.

When the first semiconductor layer 3 contains Ga, the average molar concentration of Ga in the first sub-layer 3a may be lower than the average molar concentration of Ga in the rest (that is, a site including the other sub-layers 3b and 3c other than the first sub-layer 3a) other than the first sub-layer 3a. This allows the first sub-layer 3a to have increased rigidity and also allows the reliability of the electrical connection of the first semiconductor layer 3 to the first electrode layer 2 to be high.

In particular, the average molar concentration of Ga in the first sub-layer 3a may be lower than the average molar concentration of Ga in any of the other sub-layers 3b and 3c other than the first sub-layer 3a. In this case, the first sub-layer 3a enhances the reliability of the electrical connection of the first electrode layer 2 to the first semiconductor layer 3 and increases the photoelectric conversion efficiency of the sub-layers 3b and 3c other than the first sub-layer 3a.

The molar concentration of Ga in the first sub-layer 3a may be, for example, 0.7 times or less the average molar concentration of Ga in the rest (the site including the other sub-layers 3b and 3c). From the viewpoint of enhancing obtained effects, the molar concentration of Ga in the first sub-layer 3a may be 0.5 times or less the average molar concentration of Ga in the rest. This allows the first semiconductor layer 3 to have increased rigidity and also allows the electrical connection of the first sub-layer 3a to the first electrode layer 2 to be kept good. When the first semiconductor layer 3 is made of, for example, Cu(InₓGa₁₋ₓ)Se₂, where 0≦x<1, x in the first sub-layer 3a is 0 to 0.25 and x in the second and third sub-layers 3b and 3c may be 0.25 to 0.4.

The molar concentration of Ga in the first semiconductor layer 3 may be measured by, for example, energy dispersive X-ray spectroscopy (EDS) in such a manner that a cross section thereof is observed with an electron microscope. Alternatively, the molar concentration can be measured by X-ray photoelectron spectroscopy (XPS), Auger electron spectroscopy (AES), or secondary ion mass spectrometry (SIMS) in such a manner that the first semiconductor layer 3 is scraped depthwise by sputtering.

Alternatively, when the first semiconductor layer 3 contains Ga, the average molar concentration of Ga in the first sub-layer 3a may be higher than the average molar concentration of Ga in the rest (that is, the site including the other sub-layers 3b and 3c other than the first sub-layer 3a) other than the first sub-layer 3a. This allows the first sub-layer 3a to have a high conduction band to successfully perform charge transfer and also allows the electrical connection of the first semiconductor layer 3 to the first electrode layer 2 to be kept good because the average thickness of the first sub-layer 3a is less than that of the rest.

In particular, the average molar concentration of Ga in the first sub-layer 3a may be higher than the average molar concentration of Ga in the other sub-layers 3b and 3c other than the first sub-layer 3a. In this case, charge transfer is successfully performed in the first semiconductor layer 3.

The molar concentration of Ga in the first sub-layer 3a may be, for example, 1.2 times or more the average molar concentration of Ga in the rest (the site including the other sub-layers 3b and 3c). From the viewpoint of enhancing obtained effects, the molar concentration of Ga in the first sub-layer 3a may be 1.5 times or more the average molar concentration of Ga in the rest. This allows charge transfer to be successfully performed in the first semiconductor layer 3. When the first semiconductor layer 3 is made of, for example, Cu(InₓGa₁₋ₓ)Se₂, where 0≦x<1, x in the first sub-layer 3a is 0.25 to 0.6 and x in the second and third sub-layers 3b and 3c may be 0 to 0.25.

The first semiconductor layer 3 is formed in a layered form by varying a process and conditions for forming each sub-layer. Examples of a forming process include those described below. For example, a chalcopyrite compound semiconductor layer can be formed by vapor deposition or the like in such a manner that a Group I-B element such as Cu, a Group III-B element such as In or Ga, and a Group VI-B element such as Se or S are supplied and are heated at 500° C. to 600° C. (Process A). Alternatively, the chalcopyrite compound semiconductor layer can be formed in such a manner that after a precursor layer containing the Group I-B element and the Group III-B element is formed by sputtering, the application of a source solution, or the like, the precursor layer is heated at 500° C. to 600° C. in an atmosphere containing the Group VI-B element (Process B). Alternatively, the chalcopyrite compound semiconductor layer can be formed in such a manner that after the Group VI-B element is deposited on the precursor layer formed in Process B by sputtering, the application of a source solution, or the like, the precursor layer is heated at 500° C. to 600° C. (Process C). Alternatively, the chalcopyrite compound semiconductor layer can be formed in such a manner that after a precursor layer containing the Group I-B element, the Group III-B element, and the Group VI-B element is formed by the application of a source solution containing the Group I-B element, the Group III-B element, and the Group VI-B element or the like, this precursor layer is heated at 500° C. to 600° C. (Process D).

Forming conditions include the heating temperature, the heating rate, and the like during the formation of the chalcopyrite compound semiconductor layer. Such a layered form can be obtained in such a manner that each sub-layer is prepared by appropriately selecting the forming process and the forming conditions. In this operation, the second sub-layer 3b and the third sub-layer 3c are preferably formed so as to be thicker than the first sub-layer 3a.

If different processes or different conditions are used to form neighboring some of the first to third sub-layers 3a to 3c, the first semiconductor layer 3 can be formed so as to have, but is not limited to, a distinct layered structure. That is, even if the neighboring sub-layers are formed by the same process under the same conditions, the layered structure can be obtained in such a manner that a heat dissipation step, that is, a period of stabilizing the crystal state to some extent by suppressing a crystallization reaction is provided between a step of forming one of the sub-layers and a step of forming another one. The precursor layer formed in Process D may be in a state prior to the formation of a chalcopyrite compound semiconductor crystal or in such a state that the chalcopyrite compound semiconductor crystal is formed to some extent. After such precursor layers or coatings are stacked, a laminate thereof may be heated at 500° C. to 600° C.

In the preparation of sub-layers of the first semiconductor layer 3, a plurality of voids can be formed at the interfaces between the sub-layers in such a manner that the upper surface of each sub-layer is actively heated by lamp irradiation, laser irradiation, or the like. The composition ratio of elements, such as Ga, in each sub-layer can be varied by varying the molar ratio of source elements in the sub-layer.

In the case of forming precursor layers formed as described for Processes B to D, when a precursor layer converted into the first sub-layer 3a is thinner than precursor layers converted into the second and third sub-layers 3b and 3c, the electrical connection of the first sub-layer 3a to the first electrode layer 2 can be kept better by suppressing the formation of cracks in the thin precursor layer converted into the first sub-layer 3a even though thermal stress is generated during heating. Even if cracks are caused in any one of the precursor layers, the progress of the cracks can be suppressed at boundaries between the precursor layers. In the case of heating a laminate including the thin precursor layer converted into the first sub-layer 3a and the other precursor layers, the first semiconductor layer 3 formed thereby may possibly be in such a state that the first to third sub-layers 3a to 3c are stacked as described above or may possibly have substantially a single-layer structure because the interfaces between the stacked layers disappear. When the formed first semiconductor layer 3 has such a single-layer structure because the interfaces between the stacked layers disappear, there is a process advantage that the first semiconductor layer 3 can be successfully formed by effectively suppressing cracks when the precursor layers are converted into the first semiconductor layer 3 by heating. In contrast, when the formed first semiconductor layer 3 is maintained in a layered state, there is a structural advantage that cracks can be suppressed because the formed first semiconductor layer 3 is maintained in a layered state, in addition to the process advantage.

From the viewpoint of simplifying manufacturing steps, the preparation of the first semiconductor layer 3 may include a step of forming a precursor containing the Group I-B element and the Group III-B element using a source solution containing sources of the Group I-B and III-B elements or a step of forming a precursor containing sources of the Group I-B, III-B, and VI-B elements using a source solution containing the sources of the Group I-B, III-B, and VI-B elements. Such a source solution is one prepared by dissolving the sources of the Group I-B, III-B, and VI-B elements in various solvents. Each of the sources of the Group I-B, III-B, and VI-B elements may be a corresponding one of these elements, an organic compound containing one of these elements, or an inorganic compound containing one of these elements. From the viewpoint of forming a particularly good chalcopyrite compound semiconductor, the sources of the Group I-B and III-B elements may be metal complexes and an organic solvent may be used.

For a source solution containing such metal complexes, in a site in contact with the first electrode layer 2, there is a tendency that ligands of the metal complexes bind to the first electrode layer 2 to cause a change in complex structure and an element is partially lost during heating. In the case of using, for example, a single source precursor (refer to U.S. Pat. No. 6,992,202) having an organic complex molecule containing the Group I-B element, the Group III-B element, and the Group VI-B element as a source solution, there is a tendency that the single source precursor binds to the first electrode layer 2 to cause a change in complex structure and the Group III-B element is particularly lost during heating. In a manufacturing method according to the present invention, the precursor layer converted into the first sub-layer 3a, which is in contact with the first electrode layer 2, is formed so as to be thin. Therefore, in the case of forming the precursor layer using such a source solution, even if an element is partially lost, the influence of the loss thereof can be reduced, which is excellent.

In the case of forming the first semiconductor layer 3, which is made of the Group I-III-VI compound semiconductor, using the single source precursor, the good first semiconductor layer 3 can be readily formed without using any vacuum process such as sputtering or vapor deposition, which is a high-cost process. A method of producing the single source precursor is described below. The single source precursor-producing method includes a step of preparing a first complex solution, a step of preparing a second complex solution, and a step of preparing a precipitate containing the single source precursor. Each step is described below in detail.

(Step of Preparing First Complex Solution)

The first complex solution is prepared such that a first complex containing a Lewis base and the Group I-B element is present therein. Examples of the Lewis base include organic compounds, such as P(C₆H₅)₃, As(C₆H₅)₃, and N(C₆H₅)₃, containing a Group VB element (also referred to as a group 15 element). An example of the source of the Group I-B element is an organometallic complex such as Cu(CH₃CN)₄.PF₆. An organic ligand for use in the organometallic complex is preferably weaker in basicity than the Lewis base. The following complex may be used: an organometallic complex of the Group I-B element coordinated with acetonitrile, the organometallic complex being prepared by dissolving a Group I-B element salt such as CuCl, CuCl₂, CuBr, or CuI in an organic solvent, such as acetonitrile, functioning as a ligand. Examples of an organic solvent contained in the first complex solution include acetonitrile, acetone, methanol, ethanol, and isopropanol.

A reaction producing the first complex is represented by Reaction Formula 1, wherein L is the Lewis base, [M′R′₄]⁺(X′)⁻ is the organometallic complex of the Group I-B element, [L₂M′R′₂]⁺(X′)⁻ is the first complex, where M′ is the Group I-B element, R′ is an arbitrary organic ligand, and (X′)⁻ is an arbitrary negative ion.

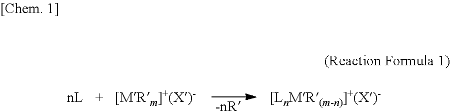

In an example of Reaction Formula 1, for example, when the Lewis base L is P(C₆H₅)₃ and the organometallic complex [M′R′ₘ]⁺(X′)⁻ of the Group I-B element is Cu(CH₃CN)₄.PF₆, the first complex [LₙM′R′₍ₘ₋ₙ₎]⁺(X′)⁻ is produced in the form of {P(C₆H₅)₃}₂Cu(CH₃CN)₂.PF₆.

(Step of Preparing Second Complex Solution)

The second complex solution is prepared such that a second complex containing a chalcogen element-containing organic compound and a Group III-B element (the Group III-B element used in the second complex solution is hereinafter referred to as the first Group III-B element) is present therein. The chalcogen element-containing organic compound is an organic compound containing a chalcogen element (the term “chalcogen element” refers to S, Se, or Te, which is a Group VI-B element). Examples of the chalcogen element-containing organic compound include thiols, selenols, and tellurols, in which the chalcogen element is bonded to an organic compound such as an acrylic compound, an allyl compound, an alkyl compound, a vinyl compound, a perfluoro compound, or a carbamate. Examples of a source of the first Group III-B element include metal salts such as InCl₃ and GaCl₃. Examples of an organic solvent contained in the second complex solution include methanol, ethanol, and propanol.

A reaction producing the second complex is represented by Reaction Formula 2, wherein E is the chalcogen element, A(ER″) is a metal salt of the chalcogen element-containing organic compound, M″(X″)₃ is a metal salt of the first Group III-B element, and A⁺[M″(ER″)₄]⁻ is the second complex, where R″ is an organic compound, A is an arbitrary positive ion, M″ is the first Group III-B element, and X″ is an arbitrary negative ion. The metal salt A(ER″) of the chalcogen element-containing organic compound is obtained by the reaction of a metal alkoxide such as NaOCH₃ with a chalcogen element-containing organic compound such as phenylselenol (HSeC₆H₅).

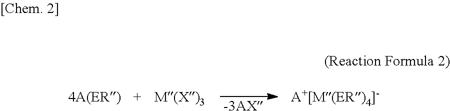

In an example of Reaction Formula 2, for example, when the metal salt A(ER″) of the chalcogen element-containing organic compound is NaSeC₆H₅ and the metal salt M″(X″)₃ of the first Group III-B element is InCl₃ or GaCl₃, the second complex A⁺[M″(ER″)₄]⁻ is produced in the form of Na⁺[In(SeC₆H₅)₄]⁻ or Na⁺[Ga(SeC₆H₅)₄]⁻, respectively.

The first Group III-B element contained in the second complex solution is not limited to one type. Several types of element may be contained therein. For example, both In and Ga may be contained in the second complex solution. In this case, the second complex solution can be prepared using a mixture of metal salt of several types of first Group III-B element as a source of the second complex solution. Alternatively, the second complex solution may be prepared in such a manner that a second complex solution containing one type of first Group III-B element is prepared for each first Group III-B element and these solutions are mixed together.

(Step of Preparing Precipitate Containing Single Source Precursor)

When the first and second complex solutions prepared as described above are mixed together, the first and second complexes react with each other to produce the precipitate containing the single source precursor. The single source precursor contains a Group I-B element such as Cu, a Group III-B element such as In or Ga, and a chalcogen element such as Se. A reaction producing the single source precursor [LₙW(ER″)₂M″(ER″)₂] is represented by Reaction Formula 3.

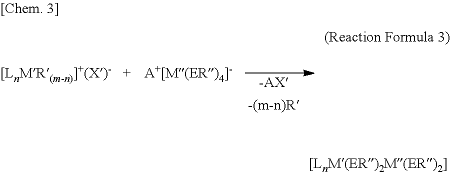

In an example of Reaction Formula 3, for example, when the first complex is {P(C₆H₅)₃}₂Cu(CH₃CN)₂.PF₆ and the second complex is Na⁺[M″(SeC₆H₅)₄]—, M″ being In and/or Ga, the single source precursor is produced in the form of {P(C₆H₅)₃}₂Cu(SeC₆H₅)₂M″(SeC₆H₅)₂.

The temperature of the reaction of the first complex with the second complex is, for example, 0° C. to 30° C. The reaction time is, for example, one to five hours. In order to remove impurities such as Na and Cl, the precipitate produced by the reaction is preferably washed by a technique such as centrifugation or filtration.

A source solution for forming a precursor layer can be prepared by dissolving the precipitate containing the single source precursor prepared as described above in an organic solvent such as toluene, pyridine, xylene, or acetone. For composition ratio adjustment, the Group I-B element and/or the Group III-B element may be added to the source solution. The source solution containing the single source precursor is applied to the first electrode layer 2 by spin coating, screen printing, dipping, spraying, or die coating and is then dried, whereby the precursor layer is formed. Drying is performed in, for example, a reducing atmosphere. The temperature during drying is, for example, 50° C. to 300° C. During the drying, organic components may be thermally decomposed.

The heating of the precursor layer allows the Group I-B element, Group III-B element, and Group VI-B element in the single source precursor to successfully react with each other to successfully prepare the Group I-III-VI compound semiconductor. The single source precursor is likely to bind to a metal such as Mo by chemical bonding including coordination bonding. The single source precursor binds to the first electrode layer 2, which contains a metal such as Mo, whereby the structure of the single source precursor is broken; hence, the single source precursor probably tends to be decomposed into a complex containing the Group I-B element and a complex containing the Group III-B element. Thus, if a precursor layer containing such a broken single source precursor is thermally treated, decomposed complexes are partially vaporized and are reduced in amount and therefore a desired composition ratio is not achieved; hence, a compound semiconductor having low photoelectric conversion efficiency is obtained. It is possible to add an element, which will be lost, to a source solution in order to achieve a desired composition ratio. This, however, tends to cause cracks; hence, it is difficult to form a good chalcopyrite compound semiconductor. However, in the present invention, since the precursor layer converted into the first sub-layer 3a, which is in contact with the first electrode layer 2, is thinner than the other precursor layers, the influence of the partial loss of an element on the first semiconductor layer 3 can be reduced. Therefore, the first semiconductor layer, which has few defects such as cracks and is good, can be successfully formed, thereby enabling the photoelectric conversion efficiency.

The photoelectric converter 10 can be obtained by depositing the second semiconductor layer 4, which is different in conductivity type from the first semiconductor layer 3, on the first semiconductor layer 3. The second semiconductor layer 4 has a conductivity type different from that of the first semiconductor layer 3 and therefore the first semiconductor layer 3 and the second semiconductor layer 4 can dissociate charges generated by light irradiation, thereby obtaining electricity. When the first semiconductor layer 3 is, for example, a p-type semiconductor, the second semiconductor layer 4 is an n-type semiconductor. Another layer may be present at the interface between the first semiconductor layer 3 and the second semiconductor layer 4. Such a layer is a buffer layer forming a heterojunction with the first semiconductor layer 3 or an i-type semiconductor layer. In this embodiment, the second semiconductor layer 4 has a function as a buffer layer forming a heterojunction with the first semiconductor layer 3 and a function as a semiconductor layer having a conductivity type different from that of the first semiconductor layer 3.

Examples of the second semiconductor layer 4 include CdS, ZnS, ZnO, In₂Se₃, In(OH, S), (Zn, In)(Se, OH), and (Zn, Mg)O. The second semiconductor layer 4 is formed by a chemical bath deposition (CBD) process or the like so as to have a thickness of 10 nm to 200 nm. The term “In(OH, S)” refers to a compound principally composed of In, Oh, and S. The term “(Zn, In)(Se, OH)” refers to a compound principally composed of Zn, In, Se, and OH. The term “(Zn, Mg)O” refers to a compound principally composed of Zn, Mg, and O.

The second electrode layer 5 is a transparent conductive film which is made of ITO, ZnO, or the like and which has a thickness of 0.05 μm to 3.0 μm. In order to increase the light transmittance and the conductivity, the second electrode layer 5 may be made of a semiconductor different in conductivity type from the first semiconductor layer 3. The second electrode layer 5 is formed by a sputtering process, a vapor deposition process, a chemical vapor deposition (CVD), or the like. The second electrode layer 5 has conductivity less than that of the second semiconductor layer 4 and is one used to extract charges generated in the first semiconductor layer 3. From the viewpoint of successfully extracting charges, the second electrode layer 5 may have a resistivity of less than 1 Ω·cm and a sheet resistance of 50 Ω/square or less.

In order to increase the absorption efficiency of the first semiconductor layer 3, the second electrode layer 5 may have light transmittance with respect to light absorbed by the first semiconductor layer 3. From the viewpoint of increasing the light transmittance, the effect of preventing optical return loss, and the effect of scattering light and from the viewpoint of successfully transmitting a current generated by photoelectric conversion, the second electrode layer 5 may have a thickness of 0.05 μm to 0.5 μm. From the viewpoint of preventing optical return loss at the interface between the second electrode layer 5 and the second semiconductor layer 4, the second electrode layer 5 and the second semiconductor layer 4 may have substantially the same refractive index.

A photoelectric conversion module can be obtained in such a manner that the photoelectric converters 10 are arranged and are electrically connected to each other. In order to readily connect the neighboring photoelectric converters 10 in series, the photoelectric converters 10 include the third electrode layer 6, which is located on the substrate 1 side of the first semiconductor layer 3 and which is spaced from the first electrode layer 2, as shown in FIGS. 1 and 2. The second electrode layer 5 and the third electrode layer 6 are electrically connected to each other through the connection conductor 7, which is attached to the first semiconductor layer 3.

The connection conductor 7 is made of a material having electrical resistivity less than that of the first semiconductor layer 3. The connection conductor 7 can be formed in such a manner that, for example, a groove is formed so as to extend through the first semiconductor layer 3 and the second semiconductor layer 4 and a conductor is provided in the groove. As for such a conductor, the connection conductor 7 can be formed in such a manner that after the groove extending through the first semiconductor layer 3 and the second semiconductor layer 4 is formed, the second electrode layer 5 is formed in the groove (refer to FIGS. 1 and 2). The connection conductor 7 may be formed by filling the groove with a conductive paste.

A collecting electrode 8 may be formed on the second electrode layer 5 as shown in FIGS. 1 and 2. The collecting electrode 8 is one for reducing the electrical resistance of the second electrode layer 5. Since the second electrode layer 5 has minimized thickness and increased light transmittance and the collecting electrode 8 is placed on the second electrode layer 5, the current generated in the first semiconductor layer 3 can be efficiently extracted. This allows the photoelectric converter 10 to have increased power generation efficiency.

The collecting electrode 8 linearly extends from, for example, an end of the photoelectric converter 10 over the connection conductor 7 as shown in FIG. 1. This allows the current generated in the first semiconductor layer 3 by photoelectric conversion to be collected in the collecting electrode 8 through the second electrode layer 5 to successfully transmit the current to the neighboring photoelectric converter 10 through the connection conductor 7. That is, the presence of the collecting electrode 8 allows the current generated in the first semiconductor layer 3 to be efficiently extracted even though the second electrode layer 5 is thin. As a result, the power generation efficiency can be increased.

From the viewpoint of suppressing the blocking of light to the first semiconductor layer 3 and from the viewpoint of achieving good conductivity, the collecting electrode 8 may have a width of 50 μm to 400 μm. The collecting electrode 8 may include a plurality of branched portions.

The collecting electrode 8 can be formed in such a manner that, for example, a pattern is printed using a metal paste containing a resin binder and a metal powder, such as an Ag powder, dispersed therein and is then cured.

The present invention is not limited to the above embodiments. Various modifications may be made without departing from the scope of the present invention.

### REFERENCE SIGNS LIST

1 substrate
2 first electrode layer
3 first semiconductor layer
3a first sub-layer
3b second sub-layer
3c third sub-layer
4 second semiconductor layer
5 second electrode layer
6 third electrode layer
7 connection conductor
8 collecting electrode
10 photoelectric converter(s)

1-9. (canceled)

10. A photoelectric converter comprising:
an electrode layer; and
a semiconductor layer on the electrode layer, containing a chalcopyrite compound semiconductor, and comprising a plurality of sub-layers, the sub-layers comprising:
a first sub-layer located closest to the electrode layer, and having a first thickness smaller than an average thickness of the rest of the plurality of sub-layers.

11. The photoelectric converter according to claim 10, wherein the first thickness is smaller than a thickness of each of the rest of the plurality of sub-layers.

12. The photoelectric converter according to claim 10, wherein the chalcopyrite compound semiconductor contains Ga, and the first sub-layer has a first average molar concentration of Ga lower than an average molar concentration of Ga in the rest of the plurality of sub-layers.

13. The photoelectric converter according to claim 12, wherein the first average molar concentration of Ga is lower than an average molar concentration of Ga in each of the rest of the plurality of sub-layers.

14. The photoelectric converter according to claim 10, wherein the chalcopyrite compound semiconductor contains Ga, and the first sub-layer has a first average molar concentration of Ga higher than an average molar concentration of Ga in the rest of the plurality of sub-layers.

15. The photoelectric converter according to claim 14, wherein the first average molar concentration of Ga is higher than an average molar concentration of Ga in each of the rest of the plurality of sub-layers.

16. The photoelectric converter according to claim 10, wherein the rest of the plurality of sub-layers comprises a second sub-layer, the second sub-layer located closest to the first sub-layer,
wherein a plurality of voids are located at a boundary between the first sub-layer and the second sub-layer.

17. The photoelectric converter according to claim 16, wherein a contact area between the first sub-layer and the second sub-layer is less than a contact area between the electrode layer and the first sub-layer.

18. A method of manufacturing a photoelectric converter, comprising:
forming a first precursor layer on an electrode layer, the first precursor layer containing a constituent element of a chalcopyrite compound semiconductor;
forming a second precursor layer on the first precursor layer, wherein the second precursor layer contains a constituent element of a chalcopyrite compound semiconductor, and is thicker than the first precursor layer; and
heating the first precursor layer and the second precursor layer to form a semiconductor layer containing the chalcopyrite compound semiconductor.

19. A photoelectric converter comprising:
an electrode layer; and
a semiconductor layer on the electrode layer, containing a chalcopyrite compound semiconductor, and comprising a plurality of sub-layers, the sub-layers:
a first sub-layer located closest to the electrode layer; and
a second sub-layer located on the first sub-layer,
wherein the first sub-layer has a thickness smaller than a thickness of the second sub-layer.

20. The photoelectric converter according to claim 19, wherein the first sub-layer has an average molar concentration of Ga lower than an average molar concentration of Ga in the second sub-layer.

21. The photoelectric converter according to claim 19, wherein the first sub-layer has an average molar concentration of Ga higher than an average molar concentration of Ga in the second sub-layer.

22. The photoelectric converter according to claim 19, wherein a plurality of voids are located at a boundary between the first sub-layer and the second sub-layer.

23. The photoelectric converter according to claim 19, wherein a contact area between the first sub-layer and the second sub-layer is less than a contact area between the electrode layer and the first sub-layer.
